(19) United States
(12) Patent Application Publication
(10) Pub. No.: US 2007/0008763 A1
(43) Pub. Date: Jan. 11, 2007

(54) Memory module and memory system having the same

(76) Inventor: Jung-Hwan Choi, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/480,546

(22) Filed: Jul. 5, 2006

(30) Foreign Application Priority Data
Jul. 11, 2005 (KR) 2005-62183

(51) Int. Cl. G11C 5/06

(52) U.S. Cl. 365/63

(57) ABSTRACT

A memory module comprises of a plurality of memory chips arranged in a rank and configured to input and output data in response to at least one of a command signal and an address signal. The memory module also comprises of a plurality of chip select pin terminals configured to transfer a plurality of chip select signals provided from an external device to the plurality of memory chips.

### BACKGROUND OF THE INVENTION

1. Field of the Invention

The present invention relates generally to memory modules, and more particularly, the present invention relates to memory modules capable of selectively enabling memory chips arranged in a single rank by using a plurality of chip select signals.

A claim of priority is made to Korean Patent Application No. 2005-62183 filed on Jul. 11, 2005, the entirety of which is incorporated herein by reference.

2. Description of the Related Art

The demand for computer system memories capable of storing large quantities of data continues to increase. One type of memory, which is widely used to meet such demand, is dynamic random-access memory (DRAM). DRAM includes various types of memories such as, for example, synchronous DRAM (SDRAM) and double data rate DRAM (DDR DRAM). In addition to DRAM type memory, other types of memories may also be used in computer systems. These memories include, for example, double data rate two SDRAM (DDR2 SDRAM), Rambus DRAM (RDRAM), and static random-access memory (SRAM).

FIG. 1 illustrates the configuration of a conventional single-rank DRAM memory module 10. Referring to FIG. 1, DRAM memory module 10 of this example includes eight DRAM chips <1:8> which form a memory “rank”. This rank of eight DRAM chips is arranged in a line on one side of a substrate (or printed circuit board). Each of the eight DRAM chips is configured to input and output 8-bit data signals DQ <0:7>. Therefore, the rank of eight DRAM chips has a ×64 data bus width. Alternatively, for example, four 16-bit DRAM chips may be used to form one rank to obtain a ×64 data bus width.

Furthermore, each of the DRAM chips <1:8> is enabled in response to a single chip select signal CS applied from a memory control chipset (not shown). Once a chip is enabled with a chip select signal CS, a command signal and an address signal may be transferred into the DRAM chips. As shown in FIG. 1, the eight DRAM chips <1:8> receive the chip select signal CS through a chip select pin terminal 9. In order for the chip select pin terminal 9 to transfer the chip select signal CS to all eight DRAM chips, the chip select pin terminal 9 of the DRAM memory module 10 is coupled together to the eight DRAM chips <1:8>.

As described above, all of the eight DRAM chips 1 to 8 are enabled by the single chip select signal CS applied through the chip select pin terminal 9. As a result, the DRAM memory module 10 inputs and outputs as much data at one time as is supported by the ×64 data bus width.

Generally, a typical DRAM chip operates in a burst mode to effectively perform a sequential read operation or write operation. In the burst mode, at least one internal address signal is generated in response to the address signal transferred from an external device to perform the sequential read operation or write operation. The generation of the internal address signal in the burst mode may improve the operation speed of the memory module that includes the DRAM chip.

A burst length BL is used to represent the number of sequential operations in the burst mode. For example, if the burst length BL is 8, the input address is An, and if only one chip enable signal CS is used to enable all eight chips, each DRAM chip operates as though the DRAM chip sequentially receives eight address signals in response to sequential input clocks. Generally, the burst length BL is set in advance into a mode register in the DRAM chip.

Accordingly, in the case of the DRAM memory module 10 described above, when the burst length BL is 8, data transferred by one command has 64×8 bits (i.e., 512 bits). This means that for every one command sent to all the eight DRAM chips, 64 bytes of data is transferred by the one command. That is, the minimum data transfer unit of the DRAM memory module 10 is 64 bytes.

However, with increases in the operation speed of the DRAM chips, the burst length of the DRAM chips has also increased to, for example, 16 or 32. In addition, with an increase in the burst length of DRAM chips, the minimum data transfer unit of a DRAM memory module also increases. For example, when the burst length is 16, the minimum data transfer unit of the memory module is 64×16 bits, i.e., 128 bytes. Alternatively, when the burst length is 32, DRAM memory module has a minimum data transfer unit of 256 bytes. This is because, as described above, the data bus width of the memory module is ×64

While conventional memory modules may be used to store data and perform various read and write operations, they suffer from various shortcomings. For example, as described above, because the DRAM chips in the DRAM memory module 10 operate together, there is a problem in that excessive data may be generated for each command signal sent to the memory module. Specifically, if the burst length is 8, for every one command sent to the memory module, 64 bytes of data are generated. Similarly, if the burst length is 16 or 32,128 bytes or 256 bytes of data, respectively, are generated. The generation of excess data my decrease the operation efficiency of the memory module.

The present disclosure is directed to overcoming one or more of the problems associated with the prior art memory modules.

### SUMMARY OF THE INVENTION

One aspect of the present disclosure includes a memory module. The memory module comprises of a plurality of memory chips arranged in a rank and configured to input and output data in response to at least one of a command signal and an address signal. The memory module also comprises of a plurality of chip select pin terminals configured to transfer a plurality of chip select signals provided from an external device to the plurality of memory chips.

Another aspect of the present disclosure includes a memory module including a plurality of memory chips configured to be arranged in one rank. The memory module comprises of k chip select pin terminals configured to transfer k chip select signals provided from an external device to the plurality of memory chips, wherein k is an integer. An input/output data bus width of the memory module is adjustable between n and n/k in response to the chip select signals.

Yet another aspect of the present disclosure includes a memory system. The memory system comprises of a memory controller configured to generate a plurality of chip select signals. The memory system also comprises of a memory module. The memory module comprises of a plurality of memory chips arranged in a rank and configured to input and output data in response to at least one of a command signal and an address signal. The memory module also comprises of a plurality of chip select pin terminals configured to transfer the plurality of chip select signals provided from the memory controller to the plurality of memory chips.

### BRIEF DESCRIPTION OF THE DRAWINGS

FIG. 1 is a schematic block diagram illustrating a configuration of a conventional single-rank dynamic random-access memory (DRAM) memory module.

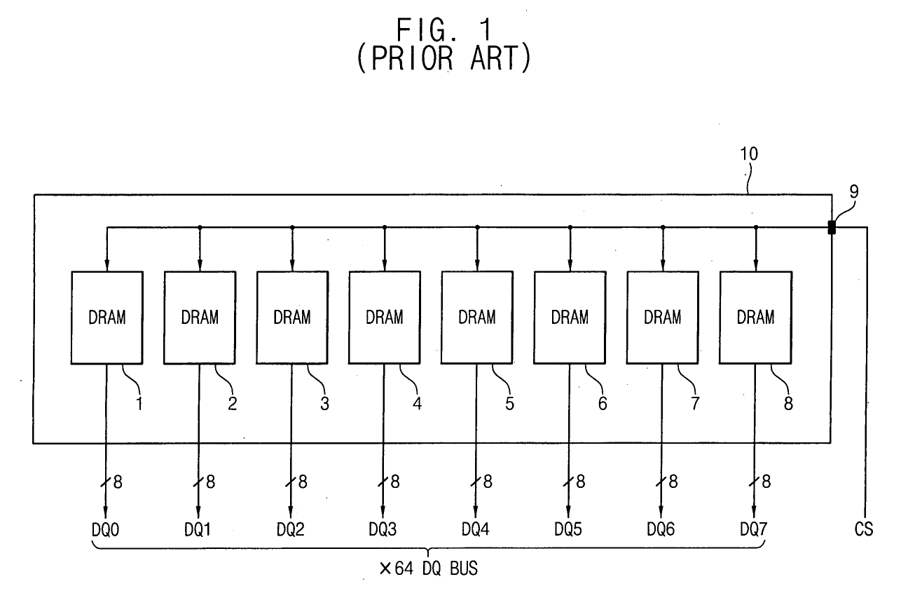

FIG. 2 is a schematic block diagram illustrating a configuration of a DRAM memory module according to an exemplary disclosed embodiment.

FIG. 3 is a schematic block diagram illustrating a configuration of a DRAM memory module according to an alternative exemplary disclosed embodiment.

FIG. 4 is a schematic block diagram illustrating a configuration of a DRAM memory module according to yet another alternative exemplary disclosed embodiment.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that although the terms first and second are used herein to describe elements, the elements should not be limited by these terms. These terms are only used to distinguish one element from another. Thus, a first element discussed below could be termed a second element and similarly, a second element may be termed a first element without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

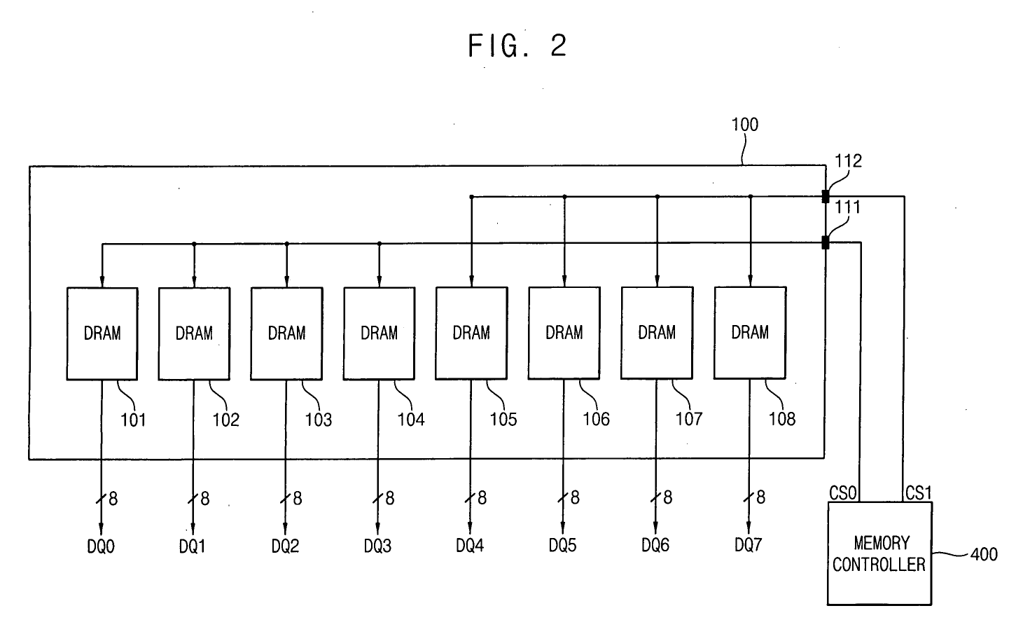

FIG. 2 is a schematic block diagram illustrating a configuration of a dynamic random-access memory (DRAM) module according to an exemplary embodiment of the present invention.

As illustrated in FIG. 2, a dynamic random-access memory (DRAM) memory module 100 includes a rank of memory chips, namely, a first DRAM chip 101, a second DRAM chip 102, a third DRAM chip 103, a fourth DRAM chip 104, a fifth DRAM chip 105, a sixth DRAM chip 106, a seventh DRAM chip 107, and an eighth DRAM chip 108. In addition, the memory module 100 also includes a first chip select pin terminal 111 and a second chip select pin terminal 112.

As mentioned above, the data bus width of a memory module depends on the number of chips in the module and the number of bits input/output from each chip. In memory module 100 of this example, the DRAM chips 101 to 108 each input and output 8-bit data input/output signals DQ0-DQ7. Signals DQ0-DQ7 may be used to perform a data read operation or a data write operation. Because each DRAM chip inputs/outputs 8-bit data signals, the DRAM memory module 100 has a ×64 data bus width.

However, the data bus width of memory module 100 can be varied with the use of a plurality of chip select signals. For example, the first chip select pin terminal 111 and second chip select pin terminal 112 are used to selectively enable/disable certain sets of DRAM chips 101 to 108 with the help of two separate chip select signals. In particular, the first chip select pin terminal 111 receives a first chip select signal CS0 from an external device. In an exemplary embodiment, this external device is memory controller 400. In addition, any other device capable of generating chip select signals may be used in place of memory controller 400. The second chip select chip 112 receives a second chip select signal CS1 provided from the memory controller 400.

The first chip select signal CS0 transferred from the first chip select pin terminal 111 is transferred to the first DRAM chip 101, the second DRAM chip 102, the third DRAM chip 103, and the fourth DRAM chip 104. Furthermore, the second chip select signal CS1 transferred from the chip select pin terminal 112 is transferred to the fifth DRAM chip 105, the sixth DRAM chip 106, the seventh DRAM chip 107, and the eighth DRAM chip 108.

The first, second, third and fourth DRAM chips 101 to 104 are enabled when the first chip select signal CS0 is at an active level, and disabled when the first chip select signal CS0 is at an inactive level. Similarly, the fifth, sixth, seventh and eighth DRAM chips 105 to 108 are enabled when the second chip select signal CS1 is at the active level and are disabled when the second chip select signal CS1 is at the inactive level.

Consequently, whether the first, second, third, and fourth DRAM chips 101 to 104 are operated or not is determined according to the first chip select signal CS0, and whether the fifth, sixth, seventh, and eighth DRAM chips 105 to 108 are operated or not is determined according to the second chip select signal CS1. In an exemplary embodiment, the first and second chip select signals CS0 and CS1 may have the same level.

In an exemplary embodiment, when the first chip select signal CS0 is at the active level and the second chip select signal CS1 is at the inactive level, the first, second, third and fourth DRAM chips 101 to 104 are enabled by the first chip select signal CS0. When DRAM chips 101 to 104 are enabled, the chips input and output data in response to a command signal and an address signal that are transferred from the memory controller 400. Furthermore, at this time, the fifth, sixth, seventh, and eighth DRAM chips 105 to 108 are disabled because the second chip select signal CS1 is at the inactive level.

Accordingly, because DRAM chips 101 to 104 input and output their 8-bit data input/output signals DQ0-DQ3, respectively, the DRAM memory module 100 has a ×32 data input/output bus width. That is, the minimum data input/output unit now becomes ×32 instead of ×64.

Similarly, when the first chip select signal CS0 is at the inactive level and the second chip select signal CS1 is at the active level, the DRAM chips 101 to 104 are disabled by the first chip select signal CS0. On the other hand, the fifth, sixth, seventh, and eighth DRAM chips 105 to 108 are enabled by the second chip select signal CS1.

When the DRAM chips 105-108 are active, because the fifth, sixth, seventh, and eighth DRAM chips input and output their 8-bit data input/output signals DQ4-DQ7, respectively, the DRAM memory module 100 has a ×32 data input/output bus width. That is, the minimum data input/output unit becomes ×32.

In yet another scenario, when the first chip select signal CS0 and the second chip select signal CS1 are both at the active level, the first, second, third, and fourth DRAM chips 101 to 104 are enabled by the first chip select signal CS0 because it is at the active level. Similarly, the fifth, sixth, seventh, and eighth DRAM chips 105 to 108 are also enabled because the second chip select signal CS1 is also at the active level. Because all eight DRAM chips, i.e., DRAM chips 101 to 108 input and output the 8-bit data input/output signals DQ0-DQ7, respectively, the DRAM memory module 100 now has a ×64 data bus width.

As discussed above, memory module 100 includes DRAM chips 101 to 108 that are arranged in one rank but are divided into two classes (one class including DRAM chips 101 to 104 and the other class including DRAM chips 104 to 108) so that each class may be selectively enabled using two chip select signals CS0 and CS1. By selectively enabling the two classes of DRAM chips 101 to 108, the minimum data input/output unit may be regulated to a ×32 or ×64 data bus width.

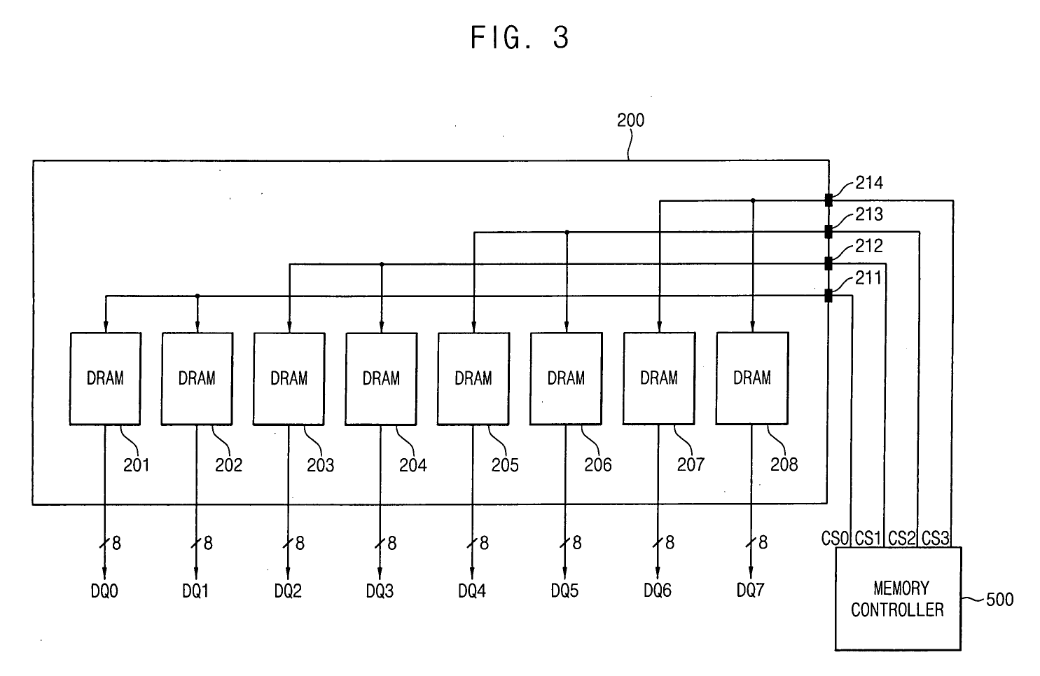

Although memory module 100 includes two chip select pin terminals, a memory module within the scope of the invention may use more than two chip select pin terminals. FIG. 3 illustrates a configuration of a DRAM memory module according to an alternate exemplary embodiment of the present invention. Referring to FIG. 3, a DRAM memory module 200 includes a first DRAM chip 201, a second DRAM chip 202, a third DRAM chip 203, a fourth DRAM chip 204, a fifth DRAM chip 205, a sixth DRAM chip 206, a seventh DRAM chip 207, and an eighth DRAM chip 208. The eight DRAM chips 201 to 208 form a rank. In addition, the memory module 200 includes four chip select pin terminals—a first chip select pin terminal 211, a second chip select pin terminal 212, a third chip select pin terminal 213, and a fourth chip select pin terminal 214.

The eight DRAM chips 201 to 208 input and output their respective 8-bit data input/output signals DQ0-DQ7 to perform a data read operation or a data write operation. Accordingly, the DRAM memory module 200 has a ×64 data bus width.

Similar to memory module 100, the data bus width of memory module 200 can be varied with the use of a plurality of chip select signals. For example, the chip select pin terminals 211, 212, 213, and 214 are used to selectively enable/disable certain sets of DRAM chips 201 to 208 with the help of four separate chip select signals. In particular, the first chip select pin terminal 211, the second chip select pin terminal 212, the third chip select pin terminal 213, and the fourth chip select pin terminal 214 receive the a first chip select signal CS0, a second chip select signal CS1, a third chip select signal CS2 and a fourth chip select signal CS3, respectively. The chip signals CS0, CS1, CS2, and CS3 may be obtained from any device configured to generate signals that are used to enable/disable a chip. In an exemplary embodiment, as shown in FIG. 3, the chip select signals CS0, CS1, CS2, and CS3 are transferred from a memory controller 500.

Each chip select pin terminal is configured to operate a select number of chips. As shown in FIG. 3, chip select pin terminal 211 operates DRAM chip 201 and DRAM chip 202, chip select pin terminal 212 operates DRAM chip 203 and DRAM chip 204, chip select pin terminal 213 operates DRAM chip 205 and 206, and chip select pin terminal 214 operates DRAM chip 207 and 208. Furthermore, each chip select pin terminal operates the corresponding DRAM chips by using a particular chip select signal. For example, the first chip select signal CS0, inputted through the first chip select pin terminal 211, is transferred to the first DRAM chip 201 and the second DRAM chip 202, the second chip select signal CS1 inputted through the second chip select pin terminal 212, is transferred to the third DRAM chip 203 and the fourth DRAM chip 204, the third chip select signal CS2 inputted through the third chip select pin terminal 213, is transferred to the fifth DRAM chip 205 and the sixth DRAM chip 206, and the fourth chip select signal CS3 inputted through the fourth chip select pin terminal 214, is transferred to the seventh DRAM chip 207 and the eighth DRAM chip 208.

The operation of each DRAM chip is based on the state of the corresponding chip select signal. For example, the first DRAM chip 201 and the second DRAM chip 202 are enabled when the first chip select signal CS0 is at the active level and are disabled when the first chip select signal CS0 is at the inactive level. Similarly, the third DRAM chip 203 and the fourth DRAM chip 204 are enabled when the second chip select signal CS1 is at the active level and are disabled when the second chip select signal CS1 is at the inactive level. Furthermore, the fifth DRAM chip 205 and the sixth DRAM chip 206 are enabled when the third chip select signal CS2 is at the active level and are disabled when the third chip select signal CS2 is at the inactive level. In addition, the seventh DRAM chip 207 and the eighth DRAM chip 208 are enabled when the fourth chip select signal CS3 is at the active level and are disabled when the fourth chip select signal CS3 is at the inactive level.

In an exemplary embodiment, the four chip select signals CS0, CS1, CS2, and CS3 may have substantially the same level.

In an exemplary embodiment, when the first chip select signal CS0 is at the active level and the second, third, and fourth chip select signals CS1, CS2, and CS3 are at the inactive level, the first DRAM chip 201 and the second DRAM chip 202 are enabled by the first chip select signal CS0. On the other hand, the other DRAM chips 203 to 208 are all disabled because the second, third and fourth chip select signals CS1, CS2, and CS3 are at the inactive level.

Consequently, because the first DRAM chip 201 and the second DRAM chip 202 input and output their respective 8-bit data input/output signals DQ0 and DQ1, the DRAM memory module 200 has a ×16 bit data input/output bus width. That is, the minimum data input/output unit becomes 116.

In a different scenario, when the first chip select signal CS0 and the second chip select signal CS1 are at the active level and the third chip select signal CS2 and the fourth chip select signal CS3 are at the inactive level, the first DRAM chip 201, the second DRAM chip 202, the third DRAM chip 203 and the fourth DRAM chip 204 are enabled by the first and second chip select signals CS0 and CS1. On the other hand, the fifth, sixth, seventh, and eighth DRAM chips 205 to 208 are disabled because the third and fourth chip select signals CS2 and CS3 are at the inactive level. Therefore, because the first, second, third, and fourth DRAM chips 201 to 204 input and output their respective 8-bit data input/output signals DQ0-DQ3, the DRAM memory module 200 now has a ×32 data input/output bus width. That is, the minimum data input/output unit becomes ×32.

In yet another scenario, when the first, second, third, and fourth chip select signals CS0 through CS3 are all at the active level, the, first, second, third, fourth, fifth, sixth, seventh, and eight DRAM chips 201, 202, 203, 204, 205, 206, 207, and 208 are all enabled. Therefore, because the eight DRAM chips 201 to 208 input and output their respective 8-bit data input/output signals DQ0-DQ7, the DRAM memory module 200, in this case, has a ×64 data bus width.

Thus, the DRAM chips 201 to 208 that are arranged in one rank are actually divided into four classes (the first class including DRAM chips 201 and 202, the second class including DRAM chips 203 and 204, the third class including DRAM chips 205 and 206, and the fourth class including DRAM chips 207 and 208,) to be selectively enabled through four chip select signal CS0-CS3, so that the minimum data input/output unit may be regulated to a data bus width of ×16, ×32, ×48, or ×64.

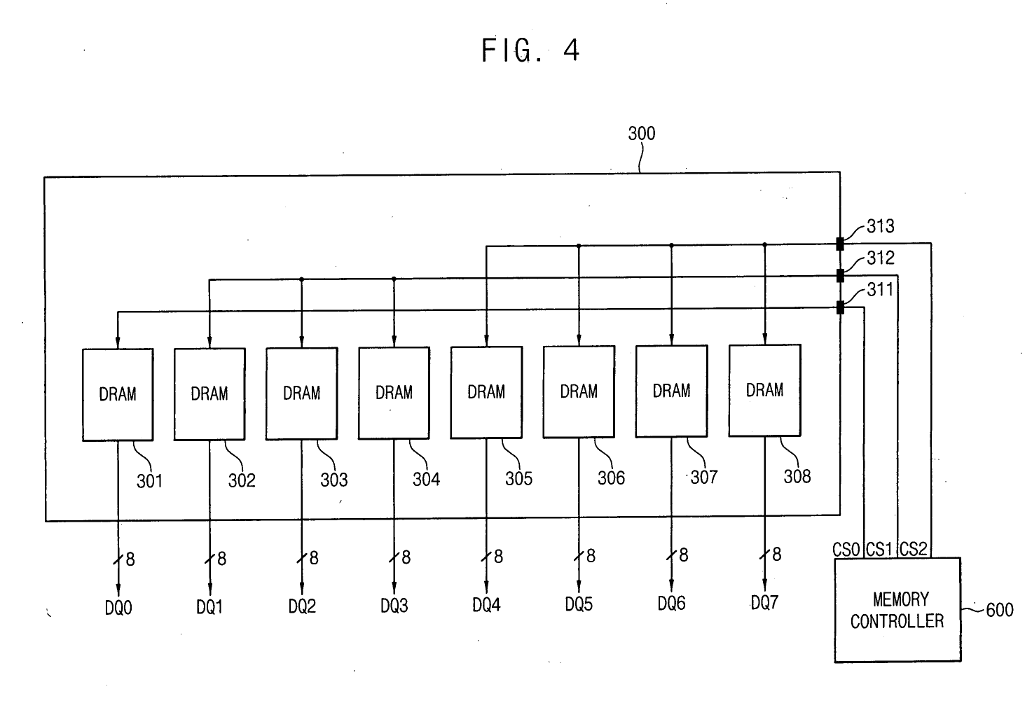

One skilled in the art will appreciate that various other combinations of chip select pin terminals and chip select signals may be used to regulate the data bus width of a memory module. For example, FIG. 4 illustrates a configuration of a DRAM memory module according to yet another exemplary embodiment of the present invention.

Referring to FIG. 4, a DRAM memory module 300 includes a first DRAM chip 301, a second DRAM chip 302, a third DRAM chip 303, a fourth DRAM chip 304, a fifth DRAM chip 305, a sixth DRAM chip 306, a seventh DRAM chip 307 and an eighth DRAM chip 308. The eight DRAM chips 301-308 form a rank. In addition, the memory module 300 includes three chip select pin terminals—a first chip select pin terminal 311, a second chip select pin terminal 312, and a third chip select pin terminal 313.

The eight DRAM chips 301 to 308 input and output their respective 8-bit data input/output signals DQ0-DQ7 to perform a data read operation or a data write operation. Accordingly, the DRAM memory module 300 has a ×64 data bus width.

Similar to memory module 100 and memory module 200, the data bus width of memory module 300 can be varied with the use of a plurality of chip select signals. For example, the chip select pin terminals 311, 312, and 313 are used to selectively enable/disable certain sets of DRAM chips 301 to 308 with the help of three separate chip select signals. In particular, the first chip select pin terminal 311, the second chip select pin terminal 312 and the third chip select pin terminal 313 receive a first chip select signal CS0, a second chip select signal CS1, and a third chip select signal CS2, respectively. In an exemplary embodiment, as shown in FIG. 4, the chip select signals CS0, CS1, and CS2 are transferred from a memory controller 600.

Each chip select pin terminal is configured to operate a select number of chips. As shown in FIG. 4, chip select pin terminal 311 operates DRAM chip 301, chip select pin terminal 312 operates DRAM chips 302, 303, and 304, and chip select pin terminal 313 operates DRAM chips 305, 306, 307, and 308. Furthermore, each chip select pin terminal operates the corresponding DRAM chips by using a particular chip select signal. For example, the first chip select signal CS0 inputted through the first chip select pin terminal 311, is transferred to the first DRAM chip 301, the second chip select signal CS1 inputted through the second chip select pin terminal 312, is transferred to the second DRAM chip 302, the third DRAM chip 303 and the fourth DRAM chip 304, and the third chip select signal CS2 inputted through the third chip select pin terminal 313, is transferred to the fifth DRAM chip 305, the sixth DRAM chip 306, the seventh DRAM chip 307, and the eighth DRAM chip 308.

The operation of each DRAM chip is based on the state of the corresponding chip select signal. For example, the first DRAM chip 301 is enabled when the first chip select signal CS0 is at the active level and is disabled when the first chip select signal CS0 is at the inactive level. Similarly, the second DRAM chip 302, the third DRAM chip 303, and the fourth DRAM chip 304 are enabled when the second chip select signal CS1 is at the active level and are disabled when the second chip select signal CS1 is at the inactive level. Furthermore, the fifth DRAM chip 305, the sixth DRAM chip 306, the seventh DRAM chip 307, and the eighth DRAM chip 308 are enabled when the third chip select signal CS2 is at the active level and are disabled when the third chip select signal CS2 is at the inactive level.

In one embodiment of the present invention, the three chip select signals CS0-CS2 may have substantially the same level.

In an exemplary embodiment, when the first chip select signal CS0 is at the active level and the second and third chip select signals CS1 and CS2 are at the inactive level, the first DRAM chip 301 is enabled by the first chip select signal CS0. On the other hand, the other DRAM chips 302 to 308 are all disabled because the second and third chip select signals CS1 and CS2 are at the inactive level.

Consequently, because the first DRAM chip 301 inputs and outputs the 8-bit data input/output signal DQ0, the DRAM memory module 300 has a ×8 data bus width. That is, the minimum data input/output unit becomes ×8.

In a different scenario, when the first chip select signal CS0 and the second chip select signal CS1 are at the active level and the third chip select signal CS2 is at the inactive level, the first DRAM chip 301, the second DRAM chip 302, the third DRAM chip 303 and the fourth DRAM chip 304 are enabled by the first and second chip select signals CS0 and CS1. On the other hand, the fifth, sixth, seventh, and eighth DRAM chips 305 to 308 are disabled because the third chip select signal CS2 is at the inactive level.

Therefore, because the first, second, third, and fourth DRAM chips 301 to 304 input and output their respective 8-bit data input/output signals DQ0-DQ3, the DRAM memory module 300 now has a ×32 data input/output bus width. That is, the minimum data input/output unit becomes ×32.

In yet another scenario, when the first, second and third chip select signals CS0-CS2 are all at the active level, all the eight DRAM chips 301 to 308 are enabled,

Because the eight DRAM chips 301 to 308 input and output their respective 8-bit data input/output signals DQ0-DQ7, the DRAM memory module 300 now has a ×64 data bus width.

Thus, the DRAM chips 301 to 308 that are arranged in one rank are actually divided into three classes (the first class including DRAM chip 301, the second class including DRAM chips 302, 303, and 304, and the third class including DRAM chips 305, 306, 307, and 308,) to be selectively enabled through three chip select signals CS0-CS2, so that the minimum data input/output units may be regulated to a data bus width of ×8, 9×24, ×32, or ×64.

The disclosed memory modules may be used in any system that includes memory modules. By selectively enabling/disabling memory chips within the memory module, the minimum data bus width of the memory module may be regulated. This regulation of the data bus width may increase the efficiency of the memory module because only the required amount of data may be generated based on the number of enabled memory chips in the memory module. In addition, the power consumption of the memory module may be reduced because only the memory chips that are enabled have to be driven in the memory module. For example, the DRAM chips may be selectively driven by setting the DRAM chips to a power save mode or a full data width mode.

One skilled in the art will appreciate that while the disclosed embodiments describe a memory module including DRAM chips, any other type of memory chip may be used in the disclosed memory modules. For example, SRAM, SDRAM, DDR DRAM, and other such memory chips may also be used in the disclosed memory modules without departing from the scope of the invention.

It will be apparent to those skilled in the art that various modifications and variations can be made in the disclosed memory modules without departing from the scope of the disclosure. Additionally, other embodiments of the disclosed system will be apparent to those skilled in the art from consideration of the specification. It is intended that the specification and the examples be considered exemplary only, with a true scope of the disclosure being indicated by the following claims and their equivalents.

What is claimed is:

1. A memory module comprising:
two or more memory chips arranged in a rank, each of the memory chips configured to input and output data in response to a command signal and an address signal; and
two or more chip select pin terminals configured to transfer two or more respective chip select signals provided from an external device, each of the chip select signals being transferred to one or more of the memory chips.

2. The memory module of claim 1, wherein the number of the memory chips is 8.

3. The memory module of claim 2, wherein each of the memory chips inputs and outputs 8-bit data.

4. The memory module of claim 2, wherein the number of the chip select pin terminals is in a range of 2 through 8 both inclusive.

5. The memory module of claim 2, wherein a minimum unit of data input and output by the memory module is one of 8 bits, 16 bits, 24 bits, 32 bits, 40 bits, 48 bits, 56 bits and 64 bits.

6. The memory module of claim 1, wherein each memory chip is enabled when a chip select signal transferred thereto is at an active level, and the memory chip is disabled when the chip select signal transferred thereto is at an inactive level.

7. The memory module of claim 1, wherein each memory chip is a dynamic random-access memory (DRAM) chip.

8. The memory module of claim 1, wherein the chip select signals have substantially the same signal level as one another.

9. A memory module comprising:
two or more memory chips arranged in one rank;
k chip select terminals configured to respectively transfer k chip select signals provided from an external device to the memory chips, wherein k is an integer,
wherein an input/output data bus width of the memory module is adjustable between n and n/k in response to the chip select signals.

10. The memory module of claim 9, wherein n is 64.

11. The memory module of claim 10, wherein the number of the memory chips is 8.

12. The memory module of claim 11, wherein each of the memory chips inputs and outputs 8-bit data.

13. The memory module of claim 10, wherein k is 2, 4 or 8.

14. The memory module of claim 10, wherein the input/output data bus width is adjustable to 8 bits, 16 bits, 24 bits, 32 bits, 40 bits, 48 bits, 56 bits and 64 bits.

15. The memory module of claim 9, wherein each memory chip is enabled when a chip select signal transferred thereto is at an active level and disabled when the chip select signal transferred thereto is at an inactive level.

16. The memory module of claim 9, wherein each memory chip is a dynamic random-access memory (DRAM) chip.

17. The memory module of claim 9, wherein the chip select signals have substantially the same signal level as one another.

18. A memory system comprising:
a memory controller configured to generate two or more chip select signals; and
a memory module which comprises (a) two or more memory chips arranged in a rank, each of the memory chips configured to input and output data, and (b) two or more chip select pin terminals configured to transfer the two or more respective chip select signals provided from the memory controller, each of the chip select signals being transferred to one or more of the memory chips.

19. The memory system of claim 18, wherein the number of the memory chips is 8.

20. The memory system of claim 19, wherein each of the memory chips inputs and outputs 8-bit data.

21. The memory system of claim 19, wherein the number of the chip select pin terminals is in a range of 2 through 8 both inclusive.

22. The memory system of claim 19, wherein the minimum data input/output unit of the memory module is adjustable to one of 8 bits, 16 bits, 24 bits, 32 bits, 40 bits, 48 bits, 56 bits and 64 bits in accordance with the chip select signals.

23. The memory system of claim 18, wherein each memory chip is enabled when a chip select signal transferred thereto is at an active level, and the memory chip is disabled when the chip select signal transferred thereto is at an inactive level.

24. The memory system of claim 18, wherein each memory chip is a dynamic random-access memory (DRAM) chip.

25. The memory system of claim 18, wherein the chip select signals have substantially the same signal level as one another.

26. The memory system of claim 18, wherein the memory controller transfers a command signal and an address signal to the memory chips.

27. The memory system of claim 26, wherein each of the memory chips inputs and outputs data in response to the command signal and the address signal when the respective memory chips are enabled by the respective chip select signals.
